(19) United States
(12) Patent Application Publication
(10) Pub. No.: US 2024/0302912 A1
(43) Pub. Date: Sep. 12, 2024

(54) Touch panel for electronic paper display

(71) Applicant: NOVATEK Microelectronics Corp., Hsin-Chu (TW)

(72) Inventors: Yu-Ying Tang, Taoyuan City (TW); Chih-Chang Lai, Taichung City (TW)

(73) Assignee: NOVATEK Microelectronics Corp., Hsin-Chu (TW)

(21) Appl. No.: 18/508,245

(22) Filed: Nov. 14, 2023

Related U.S. Application Data
(60) Provisional application No. 63/451,233, filed on Mar. 10, 2023.

(51) Int. Cl. G06F 3/041; G02F 1/1333; G02F 1/1368; G02F 1/167; G06F 3/044; H01L 27/12

(52) U.S. Cl. CPC G06F 3/0412; G02F 1/13338; G02F 1/1368; G02F 1/167; G06F 3/0443; H01L 27/124

(57) ABSTRACT

A touch panel includes a first substrate, a second substrate, a display material layer and a cover layer. A plurality of thin-film transistors (TFTs) of a plurality of pixels are deployed on the first substrate, wherein the plurality of pixels have a plurality of source lines and a plurality of gate lines. A common electrode is deployed on a second substrate. The display material layer is deployed between the first substrate and the second substrate. The cover layer is capable of being contacted by a touch object. The first substrate is located between the cover layer and the second substrate. At least one line of the plurality of source lines and the plurality of gate lines forms at least one touch sensing electrode.

### CROSS REFERENCE TO RELATED APPLICATIONS

This application claims the benefit of U.S. Provisional Application No. 63/451,233, filed on Mar. 10, 2023. The content of the application is incorporated herein by reference.

### BACKGROUND OF THE INVENTION

### 1. Field of the Invention

The present invention relates to a touch panel, and more particularly, to an in-cell touch panel for an electronic paper display (EPD).

### 2. Description of the Prior Art

In addition to the liquid crystal display (LCD) and organic light-emitting diode (OLED) display, the electronic paper display (EPD) has widely been used in display technology. The EPD features a non-self-luminous display scheme, where the image display is realized by reflecting environmental lights, similar to a paper or a book. The lights are reflected by using electronic inks in each pixel to achieve desired colors. Currently available EPD devices having touch functions are usually implemented by adding an out-cell touch film stuck to the surface of the main structure of an EPD panel. However, there is no in-cell touch panel for the EPD in the prior art.

### SUMMARY OF THE INVENTION

It is therefore an objective of the present invention to provide an in-cell touch panel for the electronic paper display (EPD), in order to integrate display with touch sensing functions.

An embodiment of the present invention discloses a touch panel, which comprises a first substrate, a second substrate, a display material layer and a cover layer. A plurality of thin-film transistors (TFTs) of a plurality of pixels are deployed on the first substrate, wherein the plurality of pixels have a plurality of source lines and a plurality of gate lines. A common electrode is deployed on the second substrate. The display material layer is deployed between the first substrate and the second substrate. The cover layer is capable of being contacted by a touch object. The first substrate is located between the cover layer and the second substrate. At least one line of the plurality of source lines and the plurality of gate lines forms at least one touch sensing electrode.

Another embodiment of the present invention discloses a touch panel, which comprises a first substrate, a second substrate, a display material layer and a cover layer. A plurality of thin-film transistors (TFTs) of a plurality of pixels and at least one touch sensing electrode are deployed on the first substrate, wherein the plurality of pixels have a plurality of source lines and a plurality of gate lines. A common electrode is deployed on the second substrate. The display material layer is deployed between the first substrate and the second substrate. The cover layer is capable of being contacted by a touch object. The first substrate is located between the cover layer and the second substrate. The at least one touch sensing electrode is deployed in the same layer of a manufacturing process with the plurality of source lines or the plurality of gate lines.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a touch panel according to an embodiment of the present invention.

FIG. 2A is a schematic diagram of a pixel electrode according to an embodiment of the present invention.

FIG. 2B illustrates an exemplary implementation of forming the touch sensing electrodes by using the pixel electrodes.

FIG. 3 is a schematic diagram of a pixel electrode array according to an embodiment of the present invention.

### DETAILED DESCRIPTION

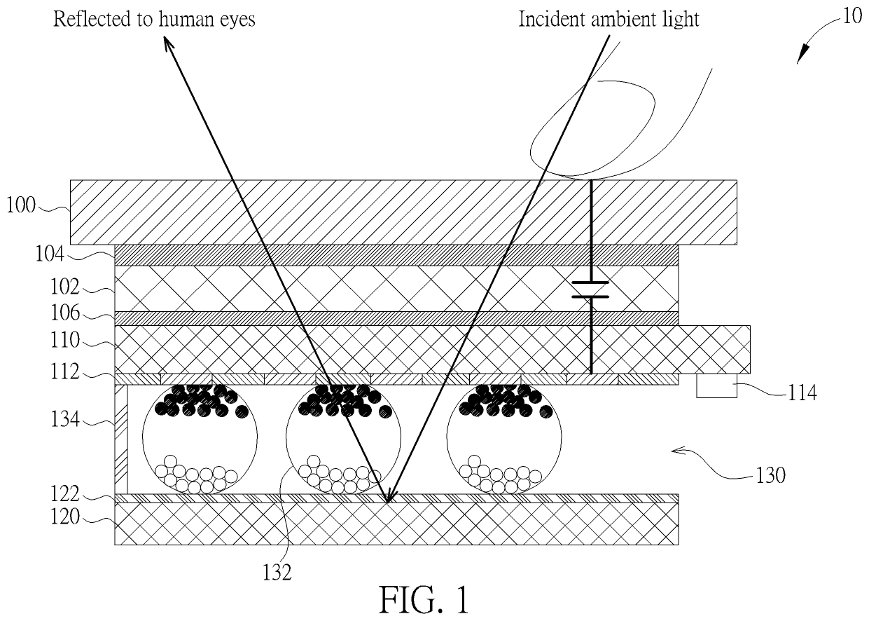

FIG. 1 is a schematic diagram of a touch panel 10 according to an embodiment of the present invention. The touch panel 10 includes a cover layer 100, a first substrate 110, a second substrate 120 and a display material layer 130. The cover layer 100 may serve as a touch surface capable of being contacted by a finger, stylus, or any other touch object. The display material layer 130 may include multiple display pixels, where each display pixel has a display material 132 having different states that represent different colors, so as to construct the full image shown on the touch panel 10. In an embodiment, the display materials 132 in the display pixels may be electronic inks (E-Inks), and thus the touch panel 10 may be an electronic paper display (EPD) integrated with touch sensing functions.

As shown in FIG. 1, the display material layer 130 may be deployed between the first substrate 110 and the second substrate 120, to be controlled by upper and lower electrode layers. More specifically, the first substrate 110 may be a thin-film transistor (TFT) substrate, on which a plurality of pixel electrodes 112 are deployed. Touch sensing electrodes are also deployed on the first substrate 110 to realize the in-cell structure. Each pixel electrode may include a TFT, which may forward display data to a display driving electrode to control the display material 132 in the display pixel, to control the state of the display material 132. The pixel electrodes 112 may further include a plurality of source lines and a plurality of gate lines, for controlling the operations of the TFTs.

In addition, a control circuit 114 may be implemented on the first substrate 110 and/or coupled to the pixel electrodes 112, to drive the TFTs to control the states of the display materials 132, so as to control the display operations. The control circuit 114 may also be capable of controlling the touch sensing operations of the touch sensing electrodes. In an embodiment, the control circuit 114 may be a touch and display driver integration (TDDI) circuit.

The second substrate 120 may be an electrode substrate, on which a common electrode 122 is deployed. The control circuit 114 may also provide a common voltage for the common electrode 122. In an embodiment, the display material layer 130 may be encapsulated by silver pastes and sealing compounds 134, which connect between the first substrate 110 and the second substrate 120 at the border of the display material layer 130. Therefore, the common voltage may be forwarded to the common electrode 122 on the second substrate 120 through the conductive silver pastes and sealing compounds 134.

The touch panel 10 may further include an encapsulation layer 102 deployed between the cover layer 100 and the first substrate 110. The encapsulation layer 102 may be formed by any appropriate transparent materials, which include, but not limited to, a plastic film and transparent organic resin. In addition, an optically clear adhesive (OCA) layer 104 may be deployed between the cover layer 100 and the encapsulation layer 102, and another OCA layer 106 may be deployed between the first substrate 110 and the encapsulation layer 102. In other words, the encapsulation layer 102 may be glued between the cover layer 100 and the first substrate 110 through the OCA.

In an embodiment, if the display materials are E-Inks, the voltage applied to each TFT and input to the display pixel may generate a vertical electric field which drives the E-Ink to turn to a specific angle, so that each pixel may show a desired color. Each display pixel may receive a respective display data, thereby constructing the full image. As shown in FIG. 1, an ambient light may be incident into the display material layer 130 from the upper side, and reflected to human eyes to show the image generated based on the twisted angles of the E-Inks. In addition, a touch object such as a finger touch may be performed on the cover layer 100 at the top of the touch panel 10. The touch sensing electrodes built on the first substrate 110 may be sensed the capacitance variation caused by the touched finger, to realize the touch sensing functions.

In order to pass the incident light and reflected light, the pixel electrodes 112, including the source lines, gate lines and/or touch sensing electrodes therein, deployed on the lower side of the first substrate 100 may be composed of transparent material(s), which may include, but not limited to, the indium tin oxide (ITO), silver nanowires, and carbon nanowires.

In order to reflect the light, the common electrode 122 deployed on the second substrate 120 at the upper side may be composed of reflective metal material(s), which may include, but not limited to, the silver, aluminum and molybdenum.

In addition, the first substrate 110 and the second substrate 120 may be implemented with the polyimide (PI) film, polyester (PET), polymethylmethacrylate (PMMA), glass, or organic packaging materials, and may be rigid or flexible circuit boards, but not limited thereto.

In such a situation, the touch sensing electrodes and the pixel electrodes 112 are both deployed at the upper side of the display material layer 130, while the common electrode 122 is deployed at the lower side of the display material layer 130. The touch signals generated by a touch object may be successfully sensed by the touch sensing electrodes located at the upper side of the display material layer 130. For example, as shown in FIG. 1, the capacitive touch signals generated by the finger may easily reach the touch sensing electrodes built on the first substrate 110. Otherwise, if the touch sensing electrodes are deployed at the lower side of the display material layer 130 while the common electrode is deployed at the upper side, the touch signals generated by a touch object might be blocked by the common electrode, thereby degrading or invalidating the touch sensing effects.

Note that the touch sensing electrodes are deployed at the upper side of the display material layer 130 to make the touch sensing operations feasible. The TFTs deployed with the touch sensing electrodes might slightly decrease the aperture ratio and emission uniformity. However, since the TFTs are usually small, these defects may be minimized if the related display driving electrodes and touch sensing electrodes are composed of transparent materials.

Furthermore, the touch panel 10 is an in-cell touch panel where the touch sensing electrodes and the display pixel electrodes 112 are both built on the same substrate 110. The number of substrates and the thickness of the panel may be minimized, thereby decreasing the product size. In addition, the integration of touch sensing electrodes and display pixel electrodes 112 allows the touch sensing functions and display functions to be commonly controlled by the same control circuit 114, which may be a TDDI integrated circuit (IC) included in a chip. In comparison, in the conventional out-cell or on-cell touch panel, the touch sensing functions and display functions are implemented on different substrates and controlled by different ICs, which may require higher circuit costs.

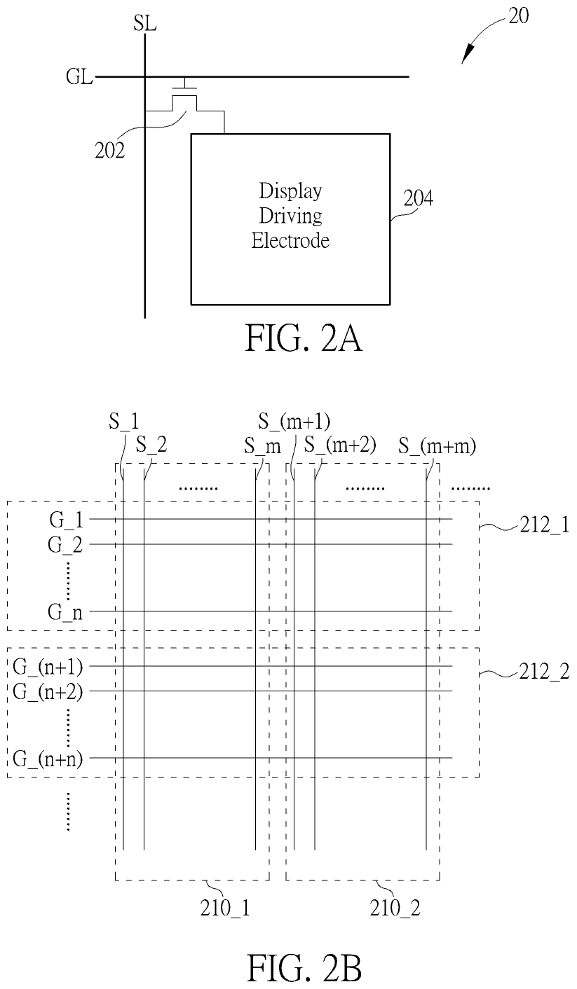

In order to realize the in-cell touch sensing, in an embodiment, the pixel electrodes 112 may be used as touch sensing electrodes. For example, FIG. 2A is a schematic diagram of a pixel electrode 20 according to an embodiment of the present invention, where the pixel electrode 20 may be a unit of the pixel electrodes 112 deployed on the first substrate 110. FIG. 2B illustrates an exemplary implementation of forming the touch sensing electrodes by using the pixel electrodes 112.

As shown in FIG. 2A, the pixel electrode 20 includes a TFT 202, a display driving electrode 204, a source line SL and a gate line GL, which may be deployed on the first substrate 110. In other words, the pixel electrodes 112 serving as the touch sensing electrodes and the display driving electrode 204 used for display control are built on the same substrate, to realize the in-cell touch panel. In an embodiment, the display driving electrode 204 and the touch sensing electrodes may be deployed in the same layer of the manufacturing process.

In the pixel electrode 20, the drain terminal and the source terminal of the TFT 202 are coupled to the display driving electrode 204 and the source line SL, respectively. The gate terminal of the TFT 202 is coupled to the gate line GL, to receive a scan signal through the gate line GL. Based on the scan signal, a display data may be forwarded through the source line SL and the TFT 202 to the display driving electrode 204 to generate a desired image.

Note that there may be multiple pixel electrodes 112 deployed on the first substrate 110, and the pixel electrodes 112 may form a TFT array connected with multiple gate lines and multiple source lines. As shown in FIG. 2B, there may be a plurality of gate lines (G_1 . . . G_n . . . ) and a plurality of source lines (S_1 . . . S_m . . . ) included in the pixel electrodes 112, where each gate line is connected to a row of TFTs, and each source line is connected to a column of TFTs.

In this embodiment, the gate lines and/or the source lines may be applied to form the touch sensing electrodes to perform touch sensing. For example, every m source lines may form a touch sensing electrode. In detail, the source lines S_1-S_m are coupled together to form a touch sensing electrode 210_1, the source lines S_(m+1)-S (m+m) are coupled together to form another touch sensing electrode 210_2, and so on. Alternatively or additionally, every n gate lines may form a touch sensing electrode. In detail, the gate lines G_1-G_n are coupled together to form a touch sensing electrode 212_1, the gate lines G_(n+1)-G_(n+n) are coupled together to form another touch sensing electrode 212_2, and so on. In this embodiment, m and n may be any appropriate integers.

Since the touch sensing and display driving operations share the same electrodes, they may be performed time-divisionally. In the display period, the gate lines and the source lines are coupled to the corresponding display driving outputs and data outputs. In the touch period, several gate lines (e.g., every n gate lines in FIG. 2B) may be coupled together to form a horizontal touch sensing electrode and commonly coupled to one touch analog front-end (AFE) circuit, and several source lines (e.g., every m source lines in FIG. 2B) may be coupled together to form a vertical touch sensing electrode and commonly coupled to one touch AFE circuit.

Preferably, this implementation and connection may realize mutual capacitance touch sensing. For example, as shown in FIG. 2B, the touch sensing electrodes 212_1 and 212_2 formed by the gate lines may be used for receiving touch driving signals from the TDDI circuit, and the touch sensing electrodes 210_1 and 210_2 formed by the source lines may be used for outputting touch sensing signals to the touch AFE circuit. Alternatively, the touch sensing electrodes 210_1 and 210_2 formed by the source lines may be used for receiving touch driving signals from the TDDI circuit, and the touch sensing electrodes 212_1 and 212_2 formed by the gate lines may be used for outputting touch sensing signals to the touch AFE circuit.

In another embodiment, the touch sensing operations may be performed by using additional electrodes other than the driving electrodes of display operations such as the gate lines and/or source lines; that is, the touch sensing electrodes are independent to the source lines and the gate lines.

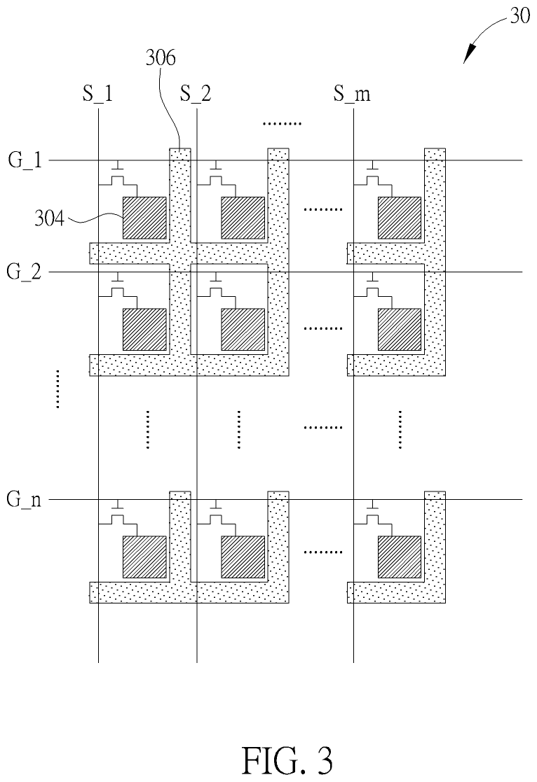

FIG. 3 is a schematic diagram of a pixel electrode array 30 according to an embodiment of the present invention. As shown in FIG. 3, in the layer of the manufacturing process where the display driving electrodes 304, the gate lines G_1-G_n and/or the source lines S_1-S_m are deployed, the sizes of the display driving electrodes 304 may be smaller than those shown in FIG. 2A, to reserve some areas for deploying the touch sensing electrodes 306. In such a situation, the touch sensing electrodes 306 may be deployed in the same layer with the source lines S_1-S_m or the gate lines G_1-G_n. In this implementation, each touch sensing electrode 306 may correspond to multiple pixel areas, and may be coupled to the TDDI circuit through a respective connecting wire.

The independent touch sensing electrodes 306 and display driving electrodes 304 may be deployed in the same layer of the manufacturing process as shown in FIG. 3, and/or may be deployed by using the same process step. For example, during the manufacturing process of the EPD touch panel, the touch sensing electrodes 306 and the display driving electrodes 304 may both be implemented with ITO, which may be stacked on the TFTs in the same process step.

In this embodiment, since the touch sensing electrodes 306 are independent to the display driving electrodes 304 and related gate lines and source lines, there is no need to perform touch sensing and display driving time-divisionally. As shown in FIG. 3, each touch sensing electrode 306 may be coupled to the TDDI circuit through a respective connecting wire, and this deployment is preferably applied to self-capacitance touch sensing. In the self-capacitance touch sensing, each touch sensing electrode 306 may receive a touch driving signal from the TDDI circuit through a connecting wire, and correspondingly output a touch sensing signal to the TDDI circuit through the same connecting wire.

Please note that the present invention aims at providing the structure of an in-cell touch panel. Those skilled in the art may make modifications and alterations accordingly. For example, in the above embodiment as shown in FIGS. 2A and 2B, the electrode implementation where the touch sensing electrodes are formed by the gate lines and/or source lines is preferably applied to mutual capacitance touch sensing. In another embodiment, this electrode implementation may also be applicable to self-capacitance touch sensing; that is, each of the touch sensing electrodes formed by the gate lines and/or source lines may receive touch driving signals and also output touch sensing signals. Similarly, in the above embodiment as shown in FIG. 3, the electrode implementation with independent touch sensing electrodes is preferably applied to self-capacitance touch sensing. In another embodiment, this electrode implementation may also be applicable to mutual capacitance touch sensing; that is, one or more of the touch sensing electrodes may be used for receiving touch driving signals and the other touch sensing electrodes may be used for outputting touch sensing signals.

In addition, in the above embodiments, the display material layer is implemented with electronic inks and the touch panel is an EPD, but the present invention is not limited thereto. For example, in another embodiment, the display material layer 130 may include liquid crystal molecules as the display materials, so as to realize a liquid crystal display (LCD) touch panel.

To sum up, the present invention provides an in-cell touch panel, where the pixel electrodes including the TFTs, gate lines and source lines are deployed on the substrate at the upper side where the touch object is detected, and the common electrode is deployed on the substrate at the lower side. Therefore, the pixel electrodes are implemented by using transparent materials for passing lights, and the common electrode is implemented by using a metal for reflecting lights. In an embodiment, one or more of the gate lines and/or the source lines may be coupled together to form the touch sensing electrodes. In another embodiment, there may be independent touch sensing electrodes deployed on the upper substrate on which the pixel electrodes are deployed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A touch panel, comprising:
a first substrate on which a plurality of thin-film transistors (TFTs) of a plurality of pixels are deployed, the plurality of pixels having a plurality of source lines and a plurality of gate lines;
a second substrate on which a common electrode is deployed;
a display material layer deployed between the first substrate and the second substrate; and
a cover layer capable of being contacted by a touch object;
wherein the first substrate is located between the cover layer and the second substrate;
wherein at least one line of the plurality of source lines and the plurality of gate lines forms at least one touch sensing electrode.

2. The touch panel of claim 1, wherein the plurality of source lines and the plurality of gate lines are composed of a transparent material.

3. The touch panel of claim 2, wherein the transparent material comprises at least one of an indium tin oxide (ITO), silver nanowires, and carbon nanowires.

4. The touch panel of claim 1, wherein the common electrode is composed of a metal material.

5. The touch panel of claim 4, wherein the metal material comprises at least one of a silver, an aluminum, and a molybdenum.

6. The touch panel of claim 1, wherein each of the plurality of TFTs is further coupled to a display driving electrode, which is deployed on the first substrate.

7. The touch panel of claim 6, wherein the display driving electrode and the at least one touch sensing electrode are deployed in the same layer.

8. The touch panel of claim 6, wherein the display driving electrode and the at least one touch sensing electrode are deployed by using a same process step of a manufacturing process.

9. The touch panel of claim 1, wherein a plurality of first source lines among the plurality of source lines are coupled together to form a first touch sensing electrode among the at least one touch sensing electrode, and a plurality of first gate lines among the plurality of gate lines are coupled together to form a second touch sensing electrode among the at least one touch sensing electrode.

10. The touch panel of claim 9, wherein the first touch sensing electrode is used for receiving a touch driving signal, and the second touch sensing electrode is used for outputting a touch sensing signal.

11. The touch panel of claim 1, wherein each of the at least one touch sensing electrode receives a touch driving signal and outputs a touch sensing signal.

12. The touch panel of claim 1, further comprising:
an encapsulation layer deployed between the cover layer and the first substrate.

13. The touch panel of claim 12, wherein the encapsulation layer is formed by at least one of a plastic film and a transparent organic resin.

14. The touch panel of claim 12, further comprising:
a first optically clear adhesive (OCA) layer deployed between the cover layer and the encapsulation layer; and
a second OCA layer deployed between the encapsulation layer and the first substrate.

15. The touch panel of claim 1, wherein the display material layer comprises electronic inks, and the touch panel is an electronic paper display (EPD) integrated with a touch sensing function.

16. A touch panel, comprising:
a first substrate on which a plurality of thin-film transistors (TFTs) of a plurality of pixels and at least one touch sensing electrode are deployed, the plurality of pixels having a plurality of source lines and a plurality of gate lines;
a second substrate on which a common electrode is deployed;
a display material layer deployed between the first substrate and the second substrate; and
a cover layer capable of being contacted by a touch object;
wherein the first substrate is located between the cover layer and the second substrate;
wherein the at least one touch sensing electrode is deployed in the same layer with the plurality of source lines or the plurality of gate lines.

17. The touch panel of claim 16, wherein the plurality of source lines and the plurality of gate lines are composed of a transparent material.

18. The touch panel of claim 17, wherein the transparent material comprises at least one of an indium tin oxide (ITO), silver nanowires, and carbon nanowires.

19. The touch panel of claim 16, wherein the common electrode is composed of a metal material.

20. The touch panel of claim 19, wherein the metal material comprises at least one of a silver, an aluminum, and a molybdenum.

21. The touch panel of claim 16, wherein each of the plurality of TFTs is further coupled to a display driving electrode, which is deployed on the first substrate.

22. The touch panel of claim 21, wherein the display driving electrode and the at least one touch sensing electrode are deployed in the same layer of a manufacturing process.

23. The touch panel of claim 21, wherein the display driving electrode and the at least one touch sensing electrode are deployed by using a same process step of a manufacturing process.

24. The touch panel of claim 16, wherein the at least one touch sensing electrode is independent to the plurality of source lines and the plurality of gate lines.

25. The touch panel of claim 16, wherein the at least one touch sensing electrode comprises a first touch sensing electrode and a second touch sensing electrode, the first touch sensing electrode is used for receiving a touch driving signal, and the second touch sensing electrode is used for outputting a touch sensing signal.

26. The touch panel of claim 16, wherein each of the at least one touch sensing electrode receives a touch driving signal and outputs a touch sensing signal.

27. The touch panel of claim 16, further comprising:
an encapsulation layer deployed between the cover layer and the first substrate.

28. The touch panel of claim 16, wherein the encapsulation layer is formed by at least one of a plastic film and a transparent organic resin.

29. The touch panel of claim 16, further comprising:
a first optically clear adhesive (OCA) layer deployed between the cover layer and the encapsulation layer; and
a second OCA layer deployed between the encapsulation layer and the first substrate.

30. The touch panel of claim 16, wherein the display material layer comprises electronic inks, and the touch panel is an electronic paper display (EPD) integrated with a touch sensing function.
